(19) United States
(12) Patent Application Publication
(10) Pub. No.: US 2026/0247918 A1
(43) Pub. Date: Aug. 20, 2026

(54) SUBSTRATE FIXING DEVICE

(71) Applicant: SHINKO ELECTRIC INDUSTRIES CO., LTD., Nagano-shi (JP)

(72) Inventors: Yuto Sendai, Nagano (JP); Keisuke Kasahara, Nagano (JP); Yusuke Muramatsu, Nagano (JP); Shun Takagi, Nagano (JP)

(21) Appl. No.: 19/543,500

(22) Filed: Feb. 18, 2026

(30) Foreign Application Priority Data
Feb. 20, 2025 (JP) 2025-026039

(51) Int. Cl. H10P 72/72; H10P 72/76

(52) U.S. Cl. CPC H10P 72/722; H10P 72/7616

(57) ABSTRACT

A substrate fixing device includes a metal component, a tubular first insulating member, an electrostatic chuck, an adhesive layer and a terminal. The metal component has a first surface, a second surface being opposed to the first surface, and a first through hole reaching the first surface and the second surface and a recess surrounding the first through hole in a plan view being formed in the first surface. The recess includes a first recess communicating with the first through hole and a second recess being shallower than the first recess and extends from the first recess in a direction away from the first through hole. The first insulating member includes a base portion provided in the first recess and having the second through hole, and a flange portion provided in the second recess and extending from the base portion in a direction away from the second through hole.

### CROSS-REFERENCE TO RELATED APPLICATIONS

This application claims priority from Japanese Patent Application No. 2025-026039, filed on Feb. 20, 2025, the entire content of which is incorporated herein by reference.

### TECHNICAL FIELD

The present disclosure relates to a substrate fixing device.

### BACKGROUND ART

In the related art, a film forming device and a plasma etching device used for manufacturing a semiconductor device each include a stage for accurately holding a substrate such as a silicon wafer in a vacuum processing chamber. As the stage, for example, a substrate fixing device that adsorbs and holds a substrate by an electrostatic chuck mounted on a base plate has been proposed.

The substrate fixing device includes a base plate, a heater provided on the base plate, and an electrostatic chuck provided on the heater. The electrostatic chuck has a built-in electrode for adsorbing the substrate. Through holes are formed in the base plate and the heater, and a terminal connected to the electrode is provided in the through holes. By supplying power to the electrode through the terminal, the substrate is adsorbed to the substrate fixing device.

### SUMMARY OF INVENTION

In the substrate fixing device of the related art, discharge may occur between metal components including the base plate and the heater and a tip end portion of the terminal during use. When the discharge occurs, an adsorption force of the substrate may decrease.

An object of the present disclosure is to provide a substrate fixing device that can reduce discharge.

According to one aspect of the present disclosure, a substrate fixing device includes a metal component, a tubular first insulating member, an electrostatic chuck, an adhesive layer and a terminal. The metal component has a first surface and a second surface on a side opposite to the first surface. The metal component has a first through hole reaching the first surface and the second surface and a recess surrounding the first through hole in a plan view being formed in the first surface. The tubular first insulating member contains zirconia. The tubular first insulating member is provided in the recess. The tubular first insulating member has a second through hole communicating with the first through hole. The electrostatic chuck has a third surface facing the first surface and including a base and an electrode built in the base. The adhesive layer bonds the metal component and the first insulating member to the electrostatic chuck. The terminal is provided in the first through hole and the second through hole. The terminal is electrically connected to the electrode. The recess includes a first recess that communicates with the first through hole and a second recess that is shallower than the first recess and extends from the first recess in a direction away from the first through hole. The first insulating member includes a base portion that is provided in the first recess and has the second through hole, and a flange portion that is provided in the second recess and extends from the base portion in a direction away from the second through hole.

According to the present disclosure, discharge can be reduced.

### BRIEF DESCRIPTION OF DRAWINGS

FIG. 1 is a cross-sectional view illustrating a substrate fixing device according to an embodiment.

FIG. 2A is a cross-sectional view illustrating a bush included in the substrate fixing device according to the embodiment.

FIG. 2B is a cross-sectional view illustrating a metal component included in the substrate fixing device according to the embodiment.

FIG. 3 is a plan view illustrating the metal component, the bush, a sleeve, and a power supply pin included in the substrate fixing device according to the embodiment.

FIG. 4 is a flowchart illustrating a method for manufacturing the substrate fixing device according to the embodiment.

FIG. 5A is a cross-sectional view (part 1) illustrating the method for manufacturing the substrate fixing device according to the embodiment.

FIG. 5B is a cross-sectional view (part 1) illustrating the method for manufacturing the substrate fixing device according to the embodiment.

FIG. 6A is a cross-sectional view (part 2) illustrating the method for manufacturing the substrate fixing device according to the embodiment.

FIG. 6B is a cross-sectional view (part 2) illustrating the method for manufacturing the substrate fixing device according to the embodiment.

FIG. 7A is a cross-sectional view (part 3) illustrating the method for manufacturing the substrate fixing device according to the embodiment.

FIG. 7B is a cross-sectional view (part 3) illustrating the method for manufacturing the substrate fixing device according to the embodiment.

FIG. 8 is a cross-sectional view illustrating a substrate fixing device according to a comparative example.

FIG. 9A is a view illustrating an outline of a tensile shear test.

FIG. 9B is a view illustrating the outline of the tensile shear test.

### DESCRIPTION OF EMBODIMENTS

Hereinafter, an embodiment of the present disclosure will be specifically described with reference to the accompanying drawings. It should be noted that, in the present specification and the drawings, components having substantially the same functional configuration are denoted by the same reference signs, and redundant description may be omitted.

### Structure of Substrate Fixing Device

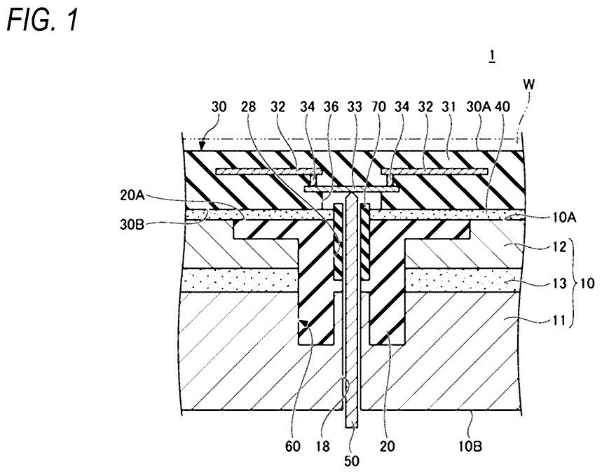

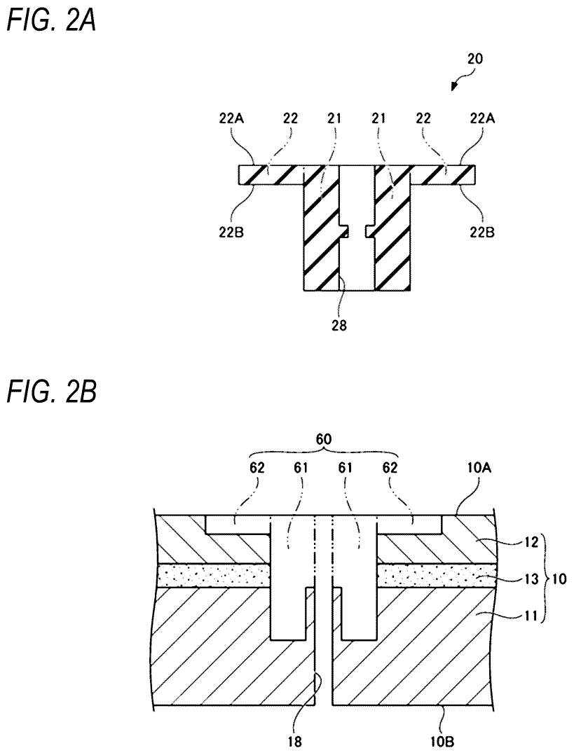

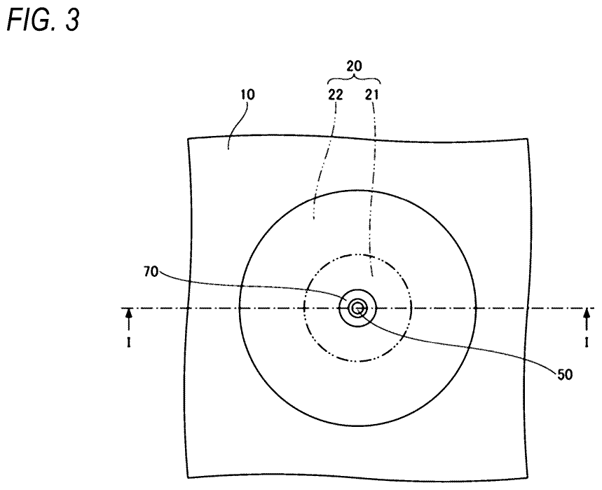

The present embodiment relates to a substrate fixing device. First, a structure of the substrate fixing device according to the embodiment will be described. FIG. 1 is a cross-sectional view illustrating the substrate fixing device according to the embodiment. FIG. 2A is a cross-sectional view illustrating a bush included in the substrate fixing device according to the embodiment. FIG. 2B is a cross-sectional view illustrating a metal component included in the substrate fixing device according to the embodiment. FIG. 3 is a plan view illustrating the metal component, the bush, a sleeve, and a power supply pin included in the substrate fixing device according to the embodiment. FIG. 1 corresponds to a cross-sectional view taken along a line I-I in FIG. 3.

As illustrated in FIGS. 1 to 3, a substrate fixing device 1 according to the embodiment includes a metal component 10, a bush 20, a sleeve 70, an electrostatic chuck 30, an adhesive layer 40, and a power supply pin 50.

In the present embodiment, for convenience, a side where the electrostatic chuck 30 is located when viewed from the metal component 10 is referred to as an upper side or one side, and a side where the metal component 10 is located when viewed from the electrostatic chuck 30 is referred to as a lower side or the other side.

The metal component 10 includes a base plate 11, a heater 12, and an adhesive layer 13. The heater 12 is bonded to the base plate 11 by the adhesive layer 13. The metal component 10 has an upper surface 10A and a lower surface 10B on a side opposite to the upper surface 10A. The heater 12 has the upper surface 10A, and the base plate 11 has the lower surface 10B. The base plate 11 and the heater 12 contain aluminum or an aluminum alloy as a main component. For example, the base plate 11 and the heater 12 are made of aluminum or an aluminum alloy. In the present disclosure, the main component refers to a component having the highest content ratio. For example, a silicone resin-based adhesive is used as a material of the adhesive layer 13. The upper surface 10A is an example of a first surface, and the lower surface 10B is an example of a second surface.

The metal component 10 is formed in, for example, a circular plate shape. A planar shape of the metal component 10 is, for example, circular. A diameter of the metal component 10 is, for example, about 200 mm to 300 mm. A thickness of the base plate 11 is, for example, about 20 to 50 mm.

A first through hole 18 is formed in the metal component 10. The first through hole 18 reaches the upper surface 10A and the lower surface 10B and penetrates the metal component 10 in the upper-lower direction. A diameter of the first through hole 18 is, for example, 5 mm to 6 mm. A recess 60 is formed in the upper surface 10A. The recess 60 surrounds the first through hole 18 in a plan view. The recess 60 is recessed toward the lower surface 10B. For example, planar shapes of the first through hole 18 and the recess 60 are circular, and the first through hole 18 and the recess 60 are formed concentrically with each other. In the present disclosure, a plan view refers to viewing an object from a direction perpendicular to the upper surface 10A, and a planar shape refers to a shape in a plan view.

The recess 60 includes a first recess 61 and a second recess 62. The first recess 61 communicates with the first through hole 18. The second recess 62 extends from the first recess 61 in a direction away from the first through hole 18, that is, in a radial direction. The second recess 62 is shallower than the first recess 61. For example, the bottom of the first recess 61 is in the base plate 11, and the bottom of the second recess 62 is in the heater 12. For example, the first recess 61 and the second recess 62 are formed concentrically with the first through hole 18. In the upper surface 10A, an edge of the recess 60 is separated from a center of the first through hole 18 by, for example, 3 mm or more and 10 mm or less.

The bush 20 is provided in the recess 60. The bush 20 contains zirconia. The bush 20 contains zirconia as a main component. The bush 20 contains zirconia with a purity of, for example, 94 mass % or more. The bush 20 preferably contains zirconia with a purity of 97 mass % or more, and more preferably contains zirconia with a purity of 99 mass % or more. The bush 20 is manufactured, for example, through firing without using a sintering aid. A second through hole 28 communicating with the first through hole 18 is formed in the bush 20. The second through hole 28 penetrates the bush 20 in an axial direction. The bush 20 has an upper surface 20A. The upper surface 20A may be flush with the upper surface 10A of the metal component 10.

The bush 20 includes a base portion 21 and a flange portion 22. The base portion 21 is provided in the first recess 61, and the second through hole 28 is formed in the base portion 21. The base portion 21 is fitted in the first recess 61. For example, the base portion 21 has a cylindrical shape. The flange portion 22 is provided in the second recess 62 and extends from the base portion 21 in a direction away from the second through hole 28, that is, in the radial direction. The flange portion 22 has an upper surface 22A and a lower surface 22B on a side opposite to the upper surface 22A. The lower surface 22B is in contact with the heater 12. The flange portion 22 is fitted in the second recess 62. The upper surface 22A is a part of the upper surface 20A. The upper surface 22A may be flush with the upper surface 10A of the metal component 10. The bush 20 is an example of a first insulating member. The upper surface 22A is an example of a fourth surface, and the lower surface 22B is an example of a fifth surface.

The electrostatic chuck 30 includes a base 31, an electrode 32, an electrode pad 33, and a via conductor 34. The electrode 32, the electrode pad 33, and the via conductor 34 are embedded in the base 31. The base 31 preferably contains alumina.

The electrostatic chuck 30 has an upper surface 30A and a lower surface 30B on a side opposite to the upper surface 30A. The lower surface 30B faces the upper surface 10A of the metal component 10. A recess 36 recessed toward the upper surface 10A is formed in a portion of the lower surface 30B overlapping the first through hole 18 in a plan view. The electrode pad 33 is exposed at the bottom of the recess 36. The electrode 32 is disposed closer to the upper surface 30A side than the electrode pad 33, and the via conductor 34 electrically connects the electrode pad 33 and the electrode 32. The lower surface 30B is an example of a third surface.

When a predetermined voltage is applied from an adsorption power supply (not illustrated) provided outside the substrate fixing device 1, the electrode 32 generates an adsorption force by static electricity between the electrode 32 and a substrate W placed on the upper surface 30A which is the substrate placement surface. Accordingly, the substrate W can be adsorbed and held on the upper surface 30A. An adsorption holding force of the electrostatic chuck 30 increases as the voltage applied to the electrode 32 increases. The electrode 32 may have a unipolar shape or a bipolar shape. Examples of the materials of the electrode 32, the electrode pad 33, and the via conductor 34 include tungsten (W) and molybdenum (Mo). The electrostatic chuck 30 is, for example, a Johnsen-Rahbek type electrostatic chuck. However, the electrostatic chuck 30 may be a Coulomb force type electrostatic chuck.

The adhesive layer 40 bonds the metal component 10 and the bush 20 to the electrostatic chuck 30. The adhesive layer 40 is in direct contact with the upper surface 10A of the metal component 10 and the upper surface 20A of the bush 20. That is, the upper surface 22A of the flange portion 22 is in direct contact with the adhesive layer 40. A primer may be provided between the lower surface 30B of the electrostatic chuck 30 and the adhesive layer 40. For example, a silicone resin-based adhesive is used as the material of the adhesive layer 40. The adhesive layer 40 contains a silicone resin. A thickness of the adhesive layer 40 is, for example, 0.15 mm.

The power supply pin 50 is provided in the first through hole 18 and the second through hole 28, and is fixed to the electrode pad 33. The power supply pin 50 is fixed to the electrode pad 33 using, for example, a conductive adhesive or solder. The power supply pin 50 is electrically connected to the electrode 32 via the electrode pad 33 and the via conductor 34. The electrode 32 is electrically connected to the adsorption power supply via the via conductor 34, the electrode pad 33, and the power supply pin 50. The power supply pin 50 is separated from an inner wall surface of the second through hole 28. The power supply pin 50 includes, for example, a linear conductor (not illustrated) and an insulator (not illustrated) that covers a side surface of the conductor in the radial direction. The power supply pin 50 is an example of a terminal.

The sleeve 70 is provided between the inner wall surface of the second through hole 28 of the bush 20 and an outer surface of the power supply pin 50. For example, the sleeve 70 has a cylindrical shape. The sleeve 70 contains, for example, polyetherimide resin as a main component. The sleeve 70 is an example of a second insulating member.

In the substrate fixing device 1 configured in this manner, as described above, a predetermined voltage is applied to the electrode 32 from the adsorption power supply to adsorb and hold the substrate W on the upper surface 30A.

### Method for Manufacturing Substrate Fixing Device

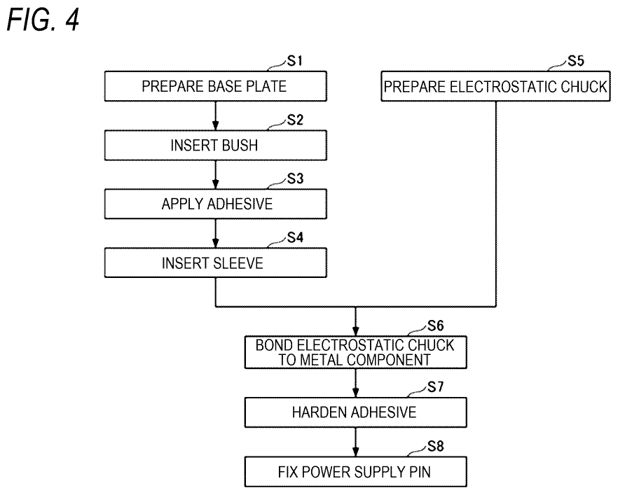

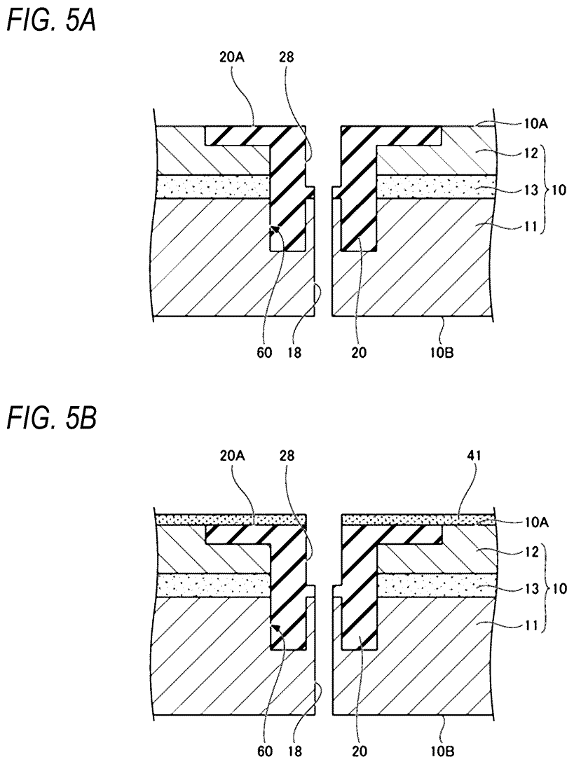

Next, a method for manufacturing the substrate fixing device 1 according to the embodiment will be described. FIG. 4 is a flowchart illustrating the method for manufacturing the substrate fixing device 1 according to the embodiment. FIGS. 5A to 7B are cross-sectional views illustrating the method for manufacturing the substrate fixing device 1 according to the embodiment.

First, as illustrated in FIG. 5A, the metal component 10 including the base plate 11, the heater 12, and the adhesive layer 13 and having the first through hole 18 and the recess 60 formed therein is prepared (step S1). Next, the bush 20 is inserted into the recess 60 (step S2).

Next, as illustrated in FIG. 5B, a liquid adhesive 41 is applied to the upper surface 10A of the metal component 10 and the upper surface 20A of the bush 20 (step S3). The adhesive 41 contains a silicone resin and becomes the adhesive layer 40 when hardened. Before the application of the adhesive 41, no primer is applied to the upper surface 10A of the metal component 10 and the upper surface 20A of the bush 20. Therefore, the upper surface 10A and the upper surface 20A are in direct contact with the adhesive 41.

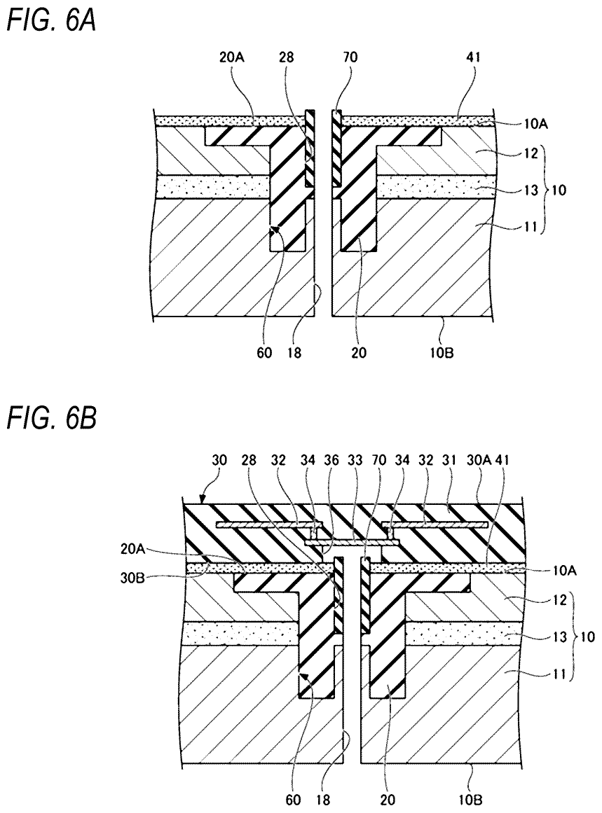

Next, as illustrated in FIG. 6A, the sleeve 70 is inserted into the second through hole 28 of the bush 20 (step S4).

Further, the electrostatic chuck 30 is prepared separately from the metal component 10 (step S5). Then, as illustrated in FIG. 6B, the electrostatic chuck 30 is bonded to the metal component 10 while the lower surface 30B of the electrostatic chuck 30 is in contact with the liquid adhesive 41 (step S6). Before the bonding of the electrostatic chuck 30, a primer may be applied to the lower surface 30B of the electrostatic chuck 30.

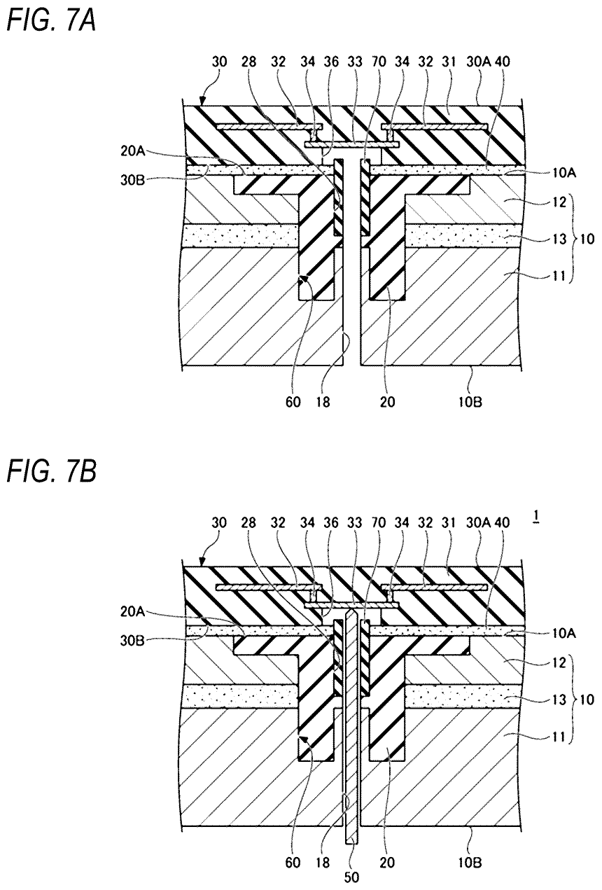

Next, as illustrated in FIG. 7A, the adhesive 41 is hardened (step S7) to form the adhesive layer 40. The adhesive layer 40 is in direct contact with the upper surface 10A and the upper surface 20A.

Next, as illustrated in FIG. 7B, the power supply pin 50 is inserted into the first through hole 18 and the second through hole 28, and the power supply pin 50 is fixed to the electrode pad 33 (step S8).

In this way, the substrate fixing device 1 can be manufactured.

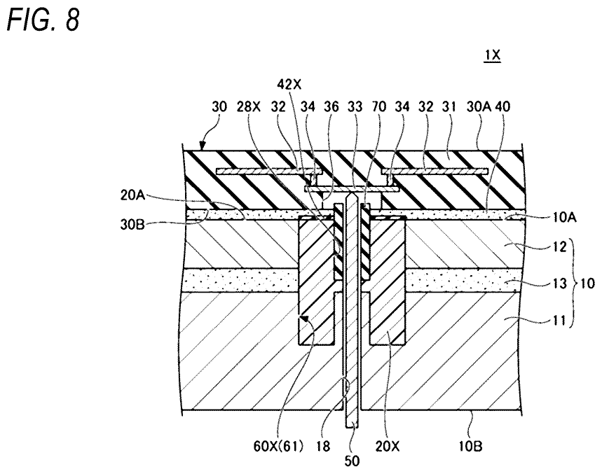

Here, effects of the substrate fixing device 1 will be described in comparison with a comparative example. FIG. 8 is a cross-sectional view illustrating a substrate fixing device according to the comparative example.

In a substrate fixing device 1X according to the comparative example, a recess 60X is formed on the upper surface 10A of the metal component 10 instead of the recess 60. The recess 60X has a portion corresponding to the first recess 61, but does not have a portion corresponding to the second recess 62. On the upper surface 10A, an edge of the recess 60X is about 1.9 mm away from the center of the first through hole 18.

The substrate fixing device 1X includes a bush 20X instead of the bush 20. The bush 20X is provided in the recess 60X. The bush 20X has a portion corresponding to the base portion 21, but does not have a portion corresponding to the flange portion 22. Further, the bush 20X contains polyether ether ketone (PEEK) resin as a main component. A primer 42X is provided on an upper surface of the bush 20X. The primer 42X is provided between the bush 20X and the adhesive layer 40. The thickness of the adhesive layer 40 is 0.076 mm.

Other configurations of the substrate fixing device 1X are the same as those of the substrate fixing device 1.

In the substrate fixing device 1, the edge of the recess 60 is farther from the center of the first through hole 18 than the edge of the recess 60X, the bush 20 has the flange portion 22, and the adhesive layer 40 is thicker than the adhesive layer 40 in the substrate fixing device 1X. Therefore, a creepage distance from a tip end of the power supply pin 50 connected to the electrode pad 33 to the upper surface 10A of the metal component 10 is longer in the substrate fixing device 1 than in the substrate fixing device 1X. For example, while the creepage distance in the substrate fixing device 1X is about 2.4 mm, the creepage distance in the substrate fixing device 1 can be about 5.2 mm, which is about 2.17 times.

In the substrate fixing device 1X, the primer 42X is provided since an adhesive strength is low between the bush 20X containing PEEK as a main component and the adhesive layer 40. On the other hand, no primer is provided in the substrate fixing device 1 since the adhesive strength between the bush 20 containing zirconia and the adhesive layer 40 is high. In a manufacturing process of the substrate fixing device 1X, the primer is applied to the upper surface of the bush 20X after the bush 20X is inserted into the recess 60X, but if there is an area where no primer is applied on the upper surface of the bush 20X due to insufficient application, a desired adhesive strength may not be obtained. Conversely, when the primer 42X is applied to the upper surface 10A of the metal component 10 by excessive application, the adhesive strength between the metal component 10 and the adhesive layer 40 decreases. As described above, when the primer 42X is used, sufficient adhesive strength may not be obtained due to excess or deficiency of the application amount, but in the substrate fixing device 1, a decrease in adhesive strength due to the primer can be avoided.

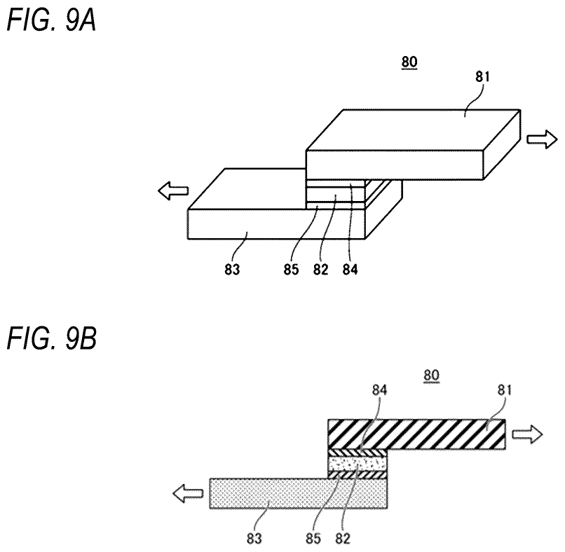

Here, a tensile shear test relating to adhesive strength performed by the present inventors will be described. FIG. 9A is a perspective view illustrating an outline of the tensile shear test, and FIG. 9B is a cross-sectional view illustrating the outline of the tensile shear test. In the tensile shear test, a test piece 80 was prepared by bonding a plate-shaped member 83 to be bonded to a plate-shaped alumina member 81 using an adhesive layer 82. The alumina member 81 and the member 83 to be bonded were bonded in a rectangular area of 25 mm×15 mm in a plan view. A primer 84 was provided between the adhesive layer 82 and the alumina member 81, and a primer 85 was provided between the adhesive layer 82 and the member 83 to be bonded depending on the test piece 80. A material of the member 83 to be bonded was three types of aluminum, PEEK, and zirconia.

A tensile load was applied in a direction (direction indicated by an arrow) parallel to a plate surface of the test piece 80. A tensile speed was 1 mm/min. The tensile shear test was performed at a room temperature. The tensile shear stress was measured three times for each condition, and an average value was calculated. Results of the tensile shear test are illustrated in Table 1 below.

TABLE 1

| Condition | Material of member | | Tensile shear |
|---|---|---|---|
| No. | 83 to be bonded | Primer 85 | stress (MPa) |
| 1 | Aluminum | Present | 0.04 |
| 2 | Aluminum | Absent | 0.31 |
| 3 | PEEK | Present | 0.28 |
| 4 | PEEK | Absent | 0.08 |
| 5 | Zirconia | Absent | 0.33 |

As illustrated in Table 1, the tensile shear stress is 0.28 MPa or more in Conditions No. 2, No. 3, and No. 5, whereas the tensile shear stress is 0.08 MPa or less in Conditions No. 1 and No. 4.

The fact that the tensile shear stress is lower in Condition No. 1 than in Condition No. 2 indicates that, in the case where the metal component 10 is formed of aluminum, the adhesive strength decreases when the primer adheres to the metal component 10. The fact that the tensile shear stress is lower in Condition No. 4 than in Condition No. 3 indicates that, in the case where the bush 20X is formed of PEEK, the adhesive strength decreases when there is a portion where no primer is applied between the bush 20X and the adhesive layer 40. The fact that the tensile shear stress is higher in Condition No. 5 than in Conditions No. 2 and No. 3 indicates that in the case where the bush 20 is formed of zirconia, sufficient adhesive strength can be obtained without the primer.

As described above, according to the substrate fixing device 1 of the embodiment, since the creepage distance from the tip end of the power supply pin 50 connected to the electrode pad 33 to the upper surface 10A of the metal component 10 is long, discharge can be reduced.

In addition, since the bush 20 contains zirconia, high adhesive strength can be obtained between the bush 20 and the adhesive layer 40 without the primer between the bush 20 and the adhesive layer 40. Since no primer is provided between the bush 20 and the adhesive layer 40, adhesion of the primer to the upper surface 10A of the metal component 10 can be prevented, and a decrease in adhesive strength due to the adhesion of the primer can be prevented. Therefore, according to the substrate fixing device 1, it is possible to stably obtain a high adhesive strength between the electrostatic chuck 30, and the metal component 10 and the bush 20. Therefore, it is possible to prevent peeling due to a decrease in adhesive strength and to reduce the discharge via the peeled portion.

The thickness of the adhesive layer 40 is preferably 0.10 mm or more and 0.20 mm or less. When the thickness of the adhesive layer 40 is 0.10 mm or more, the discharge is easily reduced. On the other hand, when the thickness of the adhesive layer 40 exceeds 0.20 mm, the thermal conductivity between the metal component 10 and the electrostatic chuck 30 may decrease.

Although the preferred embodiments and the like have been described in detail, the present disclosure is not limited to the embodiments and the like described above, and various modifications and substitutions can be made to the embodiments and the like described above without departing from the scope of the claims.

What is claimed is:

1. A substrate fixing device comprising:
a metal component having a first surface and a second surface on a side opposite to the first surface, and having a first through hole reaching the first surface and the second surface, a recess surrounding the first through hole in a plan view being formed in the first surface;
a tubular first insulating member containing zirconia, provided in the recess, and having a second through hole communicating with the first through hole;
an electrostatic chuck having a third surface facing the first surface and including a base and an electrode built in the base;
an adhesive layer bonding the metal component and the first insulating member to the electrostatic chuck; and
a terminal provided in the first through hole and the second through hole and electrically connected to the electrode, wherein
the recess includes a first recess that communicates with the first through hole and a second recess that is shallower than the first recess and extends from the first recess in a direction away from the first through hole, and
the first insulating member includes a base portion that is provided in the first recess and has the second through hole, and a flange portion that is provided in the second recess and extends from the base portion in a direction away from the second through hole.

2. The substrate fixing device according to claim 1, wherein
the first insulating member contains zirconia with a purity of 94 mass % or more.

3. The substrate fixing device according to claim 2, wherein
a portion of the metal component having the first surface is made of aluminum or an aluminum alloy.

4. The substrate fixing device according to claim 1, wherein
the adhesive layer contains a silicone resin.

5. The substrate fixing device according to claim 1, wherein
the metal component includes a base plate that has the second surface and a heater that is bonded to the base plate and has the first surface, and
the second recess is formed in the heater.

6. The substrate fixing device according to claim 5, wherein
the flange portion has a fourth surface in contact with the adhesive layer and a fifth surface in contact with the heater on a side opposite to the fourth surface.

7. The substrate fixing device according to claim 1, wherein
the base contains alumina.

8. The substrate fixing device according to claim 1, wherein
a thickness of the adhesive layer is 0.10 mm or more and 0.20 mm or less.

9. The substrate fixing device according to claim 1, further comprising
a second insulating member provided between the first insulating member and the terminal.
